(19) United States
(12) Patent Application Publication
(10) Pub. No.: US 2022/0255292 A1
(43) Pub. Date: Aug. 11, 2022

(54) SEMICONDUCTOR LASER DEVICE AND OPTOELECTRONIC BEAM DEFLECTION ELEMENT FOR A SEMICONDUCTOR LASER DEVICE

(71) Applicant: OSRAM Opto Semiconductors GmbH, Regensburg (DE)

(72) Inventors: Johann Ramchen, Hausen (DE); Andreas Fröhlich, Regensburg (DE); Martin Haushalter, Regensburg (DE); Jan Marfeld, Regensburg (DE); Massimo Cataldo Mazzillo, Regensburg (DE)

(21) Appl. No.: 17/616,277

(22) PCT Filed: May 26, 2020
(86) PCT No.: PCT/EP2020/064553

§ 371 Date: Dec. 3, 2021

(30) Foreign Application Priority Data
Jun. 7, 2019 (DE) 10 2019 115 597.5

(51) Int. Cl. H01S 5/02325; H01S 5/02255; H01S 5/0683

(52) U.S. Cl. CPC H01S 5/02325; H01S 5/02234; H01S 5/0683; H01S 5/02255

(57) ABSTRACT

A semiconductor laser device is specified comprising an edge emitting semiconductor laser diode, which emits laser light along a horizontal direction during operation, a reflector element, which deflects a first part of the laser light in a vertical direction, while a second part of the laser light continues to propagate in the horizontal direction, and a detector element, which is arranged at least partly in a beam path of the second part of the laser light. An optoelectronic beam deflection element for a semiconductor laser device is furthermore specified.

### CROSS-REFERENCE TO RELATED APPLICATIONS

This patent application is a national stage entry from International Application No. PCT/EP2020/064553, filed on May 26, 2020, published as International Publication No. WO 2020/244964 A1 on Dec. 10, 2020, and claims priority under 35 U.S.C. § 119 from German patent application 10 2019 115 597.5, filed Jun. 7, 2019, the entire contents of all of which are incorporated by reference herein.

### FIELD

The invention relates to a semiconductor laser device and an optoelectronic beam deflection element for a semiconductor laser device.

### BACKGROUND

Laser packages with edge-emitting semiconductor laser diodes usually have the diode in a housing from which the laser light is emitted according to the mounting direction and design of the diode. Due to the usual mounting method of edge-emitting semiconductor laser diodes, in the case of these diodes, such packages usually allow laser light to be coupled out and emitted via a side surface of the package, i.e. parallel, for example, to a circuit board on which the package is in turn mounted. However, if the laser light is to be emitted perpendicular to this board, it is necessary to provide a beam deflector on the board in addition to the package. If in addition the power of the laser diode is to be monitored, a photodiode must also be mounted on the board. Thus, in addition to the laser package, other components usually have to be mounted on the customer's side, which increases the space and assembly requirements.

It is at least one object of certain embodiments to specify a semiconductor laser device. At least another object of certain embodiments is to specify an optoelectronic beam deflection element for a semiconductor laser device.

These objects are achieved by the subject-matter according to the independent patent claims. Advantageous embodiments and further developments of the subject-matter are characterized in the dependent claims and are further apparent from the following description and the drawings.

### SUMMARY

According to at least one embodiment, a semiconductor laser device comprises a semiconductor laser diode. The semiconductor laser diode, which is particularly preferably designed as a laser diode chip, is provided and configured to emit light during operation, which is laser light at least when certain threshold conditions are exceeded. Accordingly, the semiconductor laser diode preferably emits laser light, which can also be abbreviated to simply light, during normal operation.

The semiconductor laser diode has at least one active layer, which is provided and configured to generate light in at least one active region during operation. The semiconductor laser diode can emit the laser light, for example, continuously or alternatively also pulsed during operation.

In particular, the active layer may be part of a semiconductor layer sequence comprising a plurality of semiconductor layers and have a main extension plane that is perpendicular to an arrangement direction of the layers of the semiconductor layer sequence. For example, the active layer may have exactly one active region. Furthermore, the semiconductor laser diode may have several active regions and be designed as a so-called broad-strip laser. For long-wave, infrared to red radiation, for example, a semiconductor layer sequence or at least one active layer based on InₓGa_{y}Al_{1-x-y}As is suitable, for red to yellow radiation, for example, a semiconductor layer sequence or at least one active layer based on InₓGa_{y}Al_{1-x-y}P is suitable, and for short-wave visible radiation, i.e. in particular in the range from green to blue light, and/or for UV radiation, for example, a semiconductor layer sequence or at least one active layer based on InₓGa_{y}Al_{1-x-y}N is suitable, with 0≤x≤1, 0≤y≤1 and x+y≤1 in each case.

According to a further embodiment, the semiconductor laser diode has an outcoupling side and a rear side opposite the outcoupling side. The outcoupling side and the rear side can in particular be side surfaces of the semiconductor laser diode, particularly preferably side surfaces of the semiconductor layer sequence, which can also be referred to as so-called facets. Via the facet on the outcoupling side, the semiconductor laser diode can emit the laser light generated in the active region during operation. Accordingly, the semiconductor laser diode is preferably an edge-emitting semiconductor laser diode. Suitable optical coatings, in particular reflective or partially reflective layers or layer sequences, can be applied to the outcoupling side and the rear side to form an optical resonator for the light generated in the active layer.

The radiation direction of the laser light generated by the semiconductor laser diode during operation is thus parallel to the main extension plane of the semiconductor layers and is referred to here and in the following as a horizontal direction. If the semiconductor laser diode in the semiconductor laser device is arranged on a mounting surface of a carrier as described further below, the radiation direction and thus the horizontal direction are particularly preferably parallel to the mounting surface. A direction perpendicular to the mounting surface is referred to here and in the following as the vertical direction.

Terms such as “perpendicular” or “parallel” can in each case designate an exact perpendicular or parallel arrangement here and in the following. Furthermore, perpendicular or parallel arrangements can also deviate from the respective exact arrangement by a small angle in each case, wherein the deviation angle can be due to a manufacturing tolerance, for example, and is smaller than or equal to 10° or smaller than or equal to 5° or smaller than or equal to 3° or smaller than or equal to 1° or preferably smaller than or equal to 0.5, for example.

According to another embodiment, the semiconductor laser device comprises a reflector element which deflects a first portion of the laser light in a vertical direction. The first portion of the laser light corresponds to less than 100% of the laser light irradiated onto the reflector element. A second portion of the laser light may correspondingly continue to propagate in a horizontal direction. In particular, the reflector element can transmit the second portion of the laser light, which is greater than 0% of the light irradiated onto the reflector element, such that the second portion of the laser light can be radiated through the reflector element. In particular, the second portion is smaller than the first portion. For example, the ratio between the first portion and the sum of the first and second portions is greater than or equal to 95% or greater than or equal to 99% or greater than or equal to 99.5%. Accordingly, the ratio between the second portion and the sum of the first and second portions may be less than or equal to 5% or less than or equal to 1% or less than or equal to 0.5%. In other words, assuming negligible losses, the reflector element reflects, for example, at least 95% or at least 99% or at least 99.5% but less than 100% of the laser light irradiated onto the reflector element, while transmitting at most 5% or at most 1% or at most 0.5% but more than 0%.

Furthermore, the semiconductor laser device comprises a detector element which is arranged at least partially in the beam path of the second portion of the laser light. At least a part of the second portion of the laser light impinges on the detector element during operation of the semiconductor laser device. The detector element may particularly preferably be configured as a photodiode and may generate an electrical signal, for example an electrical current, corresponding to the light intensity incident on the detector element, said current being a measure of the intensity of the laser light emitted by the semiconductor laser diode during operation. For example, the electrical signal is proportional to the irradiated light intensity and thus also proportional to the laser light power emitted by the semiconductor laser diode. By means of the detector element, it is thus possible to measure the power of the laser light.

According to a further embodiment, the semiconductor laser diode, the reflector element and the detector element are jointly integrated in the semiconductor laser device, the semiconductor laser device being a single component that can be mounted by a user, for example on a circuit board. Particularly preferably, the semiconductor laser diode, the reflector element and the detector element are arranged together on a common carrier, wherein the semiconductor laser device is preferably mountable, particularly preferably surface mountable, by means of the carrier. In particular, the semiconductor laser diode is mounted on a mounting surface on the carrier in such a way that the light generated by the semiconductor laser diode during operation is emitted parallel to the mounting surface along the horizontal direction towards the reflector element, while the vertical direction is aligned perpendicular to the mounting surface. An outer surface of the carrier opposite to the mounting surface may be provided and configured for mounting the semiconductor laser device, for example on a circuit board. The carrier may comprise, for example, a semiconductor material, a ceramic material, and/or a plastic material, and may be designed as a carrier provided with electrical conductor paths, terminals, and/or through-connections, such as a printed circuit board or part of a housing. Accordingly, the semiconductor laser device may comprise the carrier or a housing including the carrier. Particularly preferably, electrical contacting of the semiconductor laser diode and the detector element can also be made via the mounting surface.

According to a further embodiment, at least part of the semiconductor laser diode and/or at least part of the reflector element and/or at least part of the detector element are covered with a transparent material. “Transparent” means here and in the following in particular optically preferably as transparent as possible for the laser light. The transparent material, which in particular comprises or is made of an optically transparent plastic, can be formed, for example, as a casting or as a molding compound, so that at least part of the semiconductor laser diode and/or at least part of the reflector element and/or at least part of the detector element can be cast or molded with the transparent material, for example. In particular, the transparent material is arranged in the beam path of the laser light and can particularly preferably directly cover and at least partially enclose the described components. In particular, the transparent material can serve to optically couple the semiconductor laser diode and the detector element to the reflector element so that there is no air gap in the beam path of the laser light to the reflector element and/or in the beam path of the second portion to the detector element, respectively. The transparent material may comprise, for example, siloxanes, epoxides, acrylates, methyl methacrylates, imides, carbonates, olefins, styrenes, urethanes or derivatives thereof in the form of monomers, oligomers or polymers, and furthermore also mixtures, copolymers or compounds thereof. For example, the transparent material may comprise or be an epoxy resin, polymethyl methacrylate (PMMA), polystyrene, polycarbonate, polyacrylate, polyurethane, or preferably a silicone resin such as polysiloxane or mixtures thereof.

According to a further embodiment, at least part of the semiconductor laser diode and at least part of the detector element are covered with a non-transparent material. In particular, the non-transparent material can be applied along the vertical direction from the semiconductor laser diode and the detector element over and particularly preferably directly on at least a part of the transparent material. Particularly preferably, the non-transparent material completely covers the transparent material. The non-transparent material can, for example, reduce or even completely prevent the emission of stray light. Preferably, the non-transparent material is non-reflective or only slightly reflective. Particularly preferably, the non-transparent material is black, at least with respect to visible light. The non-transparent material may comprise one or more of the materials mentioned in connection with the transparent material, for example an epoxy, and additionally therein, for example, dyes or other fillers, for example carbon black, which cause the non-transparent material to be opaque.

According to a further embodiment, the reflector element comprises two prisms with a dielectric layer arranged between them. The dielectric layer is particularly preferably arranged at an angle of 45° to the horizontal direction. The refractive indices of the prisms, which may be formed with or of glass and/or plastic, and the refractive index of the dielectric layer, which may be a previously mentioned plastic, are selected such that partial reflection and partial transmission of the laser light can take place at the interface with the dielectric layer to split the laser light into the first and second portions described above. Preferably, the detector element is arranged horizontally behind the reflector element as seen from the semiconductor laser diode. Particularly preferably, the semiconductor laser diode, the reflector element and the detector element are arranged on a common carrier as described further above, wherein a surface of the reflector element facing away from the carrier forms a light outcoupling surface of the semiconductor laser device. In particular, the light outcoupling surface may be formed by a surface of one of the glass prisms. If the semiconductor laser device comprises a transparent material and/or a non-transparent material, the surface of the reflector element forming the light outcoupling surface is preferably free of these materials. In particular, the light outcoupling surface and a surface of the non-transparent material facing away from the carrier may form a common surface of the semiconductor laser device, which may particularly preferably be a planar surface that is perpendicular to the vertical direction.

Compared to, for example, a deflection of the laser light via a mirror, it is possible in a simple way to cover the components with the transparent and the non-transparent materials in the described manner when using the reflector element described above. Furthermore, an integration of the detector element is possible in a very simple way despite the use of an edge-emitting semiconductor laser diode and despite the covering non-transparent material.

According to a further embodiment, the semiconductor laser device comprises an optoelectronic beam deflection element, in which the reflector element and the detector element are integrated. In particular, the beam deflection element comprises a semiconductor body having a mounting surface and a front surface formed at an angle of 45° to the mounting surface. The reflector element formed by a mirror layer is applied on the front surface. The detector element is formed in the semiconductor body on the side of the mirror layer facing the mounting surface.

According to a further embodiment, the semiconductor body comprises silicon. In particular, in a method of manufacturing the beam deflection element, a silicon wafer is provided. The silicon wafer has at least a first main surface formed by a crystal surface that deviates by 9.74° from the crystallographic 100-surface. The front surface is formed from the first main surface as part of the manufacture of the beam deflection element, such that the front surface is formed by a crystal surface that deviates by 9.74° from the crystallographic 100-surface. The mounting surface is formed by etching a second main surface which is opposite the first main surface and which is formed by a crystal surface that also deviates from the crystallographic 100-surface by 9.74°. Different crystal surfaces are etched in silicon to different degrees and thus anisotropically, with, for example, etching in a direction perpendicular to the crystallographic 111-surface being significantly slower than in the other directions. By means of structured wet chemical etching of the second main surface, trenches are created in the second main surface. In particular, due to the anisotropic etching, trenches are created which have at least one side flank formed by the crystallographic 111-surface and forming the mounting surface in the subsequently completed beam deflection element. Because of the orientation of the 100-surface and the 111-surface with respect to each other, and because of the 9.74° deviation of the main surfaces from the crystallographic 100-surface, the 111-surface includes an angle of 45° with the main surfaces, so that the mounting surface in the subsequently completed beam deflection element also includes an angle of 45° with the mounting surface. In particular, the silicon wafer can be oriented, for example by suitably sawing a single crystal, so precisely that the angle between the mounting surface and the front surface deviates from 45° by less than or equal to 0.5° and preferably by less than or equal to 0.1°.

According to a further embodiment, the mirror layer forming the reflector element comprises a metal and/or a dielectric layer sequence. The thickness of the metal and/or the layer thicknesses and the layer composition of the dielectric layer sequence are selected such that partial reflection and partial transmission of the laser light can be achieved for splitting the laser light into the first and second portions described above. Depending on the wavelength of the laser light, suitable metals include, for example, Al, Au, Ag, as well as alloys therewith such as, for example, TiAl and TiAg, wherein a mirror layer made with or of Al and/or Ag may be particularly suitable for visible light and a mirror layer made with or of Au may be particularly suitable for infrared light. Depending on the wavelength, combinations of metal and semimetal oxides and metal and semimetal nitrides, for example SiO₂, Si₃N₄, TiO₂, Al₂O₃, are suitable as materials for the dielectric layer sequence.

According to a further embodiment, the detector element is at least partially formed by a p-type region and an n-type region of the semiconductor body. In particular, the p-type region and the n-type region may form a photodiode. For example, the silicon wafer provided for manufacture may be n-type. To form the detector element, a p-type region can be produced, for example, by diffusion or implantation of a suitable dopant. A p-type silicon wafer can be n-doped accordingly in one region. Particularly preferably, one of the two regions is adjacent to at least part of the front surface. In particular, the doped region produced in the silicon wafer may be at least partially adjacent to the first main surface by which the front surface is formed in the finished optoelectronic beam deflection element. Furthermore, it is also possible that a plurality of detector elements is formed by a corresponding plurality of doped regions in the semiconductor body.

For contacting the detector element, the semiconductor body preferably has, on the mounting surface and/or on at least one rear surface different from the mounting surface and the front surface, at least two electrical contact elements, at least one of which contacts the p-type region and at least one other contacts the n-type region. At least one of the electrical contact elements can be in electrical contact with an electrical through-connection which extends from a rear surface or the mounting surface to the front surface, so that the doped region adjacent to the front surface can be contacted from the front surface and is in electrical contact with a contact element by means of the through-connection. The contact elements can in particular enable surface mounting of the optoelectronic beam deflection element.

The optoelectronic beam deflection element thus has a 45° reflector and a photodiode integrated in a silicon component and can be mounted planar on a suitable carrier such as a substrate, a printed circuit board or a housing part. Together with the semiconductor laser diode on the same carrier, the optoelectronic beam deflection element can be used simultaneously for beam deflection and power monitoring, using a simple pick-and-place method and a soldering or bonding method to mount and electrically contact the beam deflection element without the need for bonding wires. Furthermore, separate detection and control of different semiconductor laser diodes, for example with different wavelengths, can be possible with small spacing in the same housing. Preferably, proven silicon processing technologies and/or MEMS technologies can be used in the manufacture.

The described semiconductor laser device enables an edge-emitting semiconductor laser diode on a surface-mountable carrier, for example as part of a housing, which is designed as a so-called top-looker package and emits laser light perpendicular to the mounting surface by means of an internal 90° deflection. Furthermore, the integrated detector element can be used, for example, for power measurement, wherein the detector element can be arranged in the beam path of the laser light in a simple manner as described. Furthermore, it may be possible here to arrange the transparent material in the beam path for protection and to avoid refractive index jumps and/or to protect the components of the semiconductor laser device by the non-transparent material.

The semiconductor laser device or at least the optoelectronic beam deflection element can be used, for example, in automotive, industrial, military or consumer applications. Particularly preferably, the semiconductor laser device or at least the optoelectronic beam deflection element can be used, for example, for lidar applications. Furthermore, the semiconductor laser device or at least the optoelectronic beam deflection element can be used in projection applications as well as in AR and/or VR applications (AR: augmented reality; VR: virtual reality).

Further advantages, advantageous embodiments and further developments will be apparent from the exemplary embodiments described below in connection with the figures.

### BRIEF DESCRIPTION OF THE DRAWINGS

In the figures:

FIG. 1 shows a schematic representation of a semiconductor laser device according to an exemplary embodiment,

FIG. 2 shows a schematic representation of a semiconductor laser device according to a further exemplary embodiment,

FIG. 3 shows a schematic representation of a semiconductor laser device according to a further exemplary embodiment,

FIGS. 4A to 4D show schematic representations of an optoelectronic beam deflection element for a semiconductor laser device according to a further exemplary embodiment,

FIGS. 5A and 5B show schematic representations of an optoelectronic beam deflection element for a semiconductor laser device according to a further exemplary embodiment,

FIGS. 6A to 6J show schematic representations of method steps of a method of manufacturing an optoelectronic beam deflection element for a semiconductor laser device according to a further exemplary embodiment, and

FIGS. 7A to 7C show schematic representations of method steps of a method of manufacturing an optoelectronic beam deflection element for a semiconductor laser device according to a further exemplary embodiment.

### DETAILED DESCRIPTION

In the exemplary embodiments and figures, equal or similar elements or elements of equal function may each be provided with the same reference signs. The elements shown and their proportions to one another are not to be regarded as true to scale; rather, individual elements, such as layers, components, structural elements and areas, may be shown exaggeratedly large for better representability and/or for better understanding.

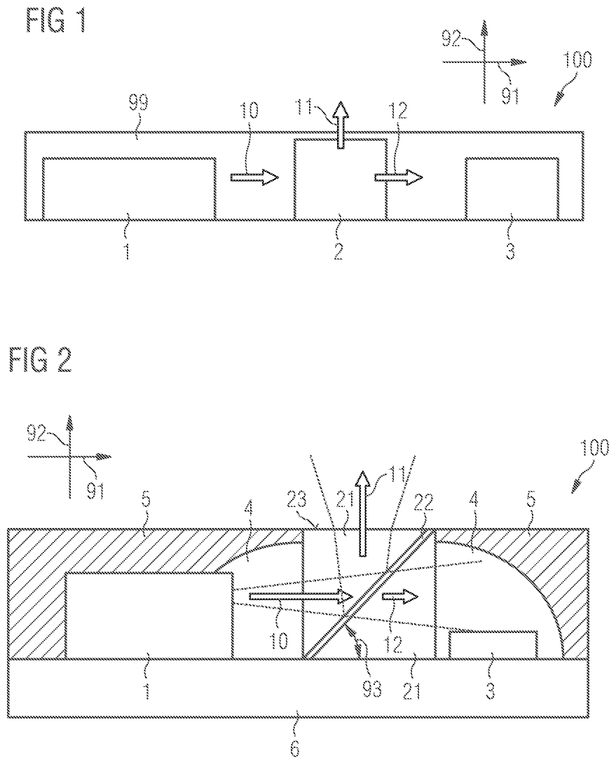

FIG. 1 shows an exemplary embodiment of a semiconductor laser device 100 comprising an edge-emitting semiconductor laser diode 1. During operation, the semiconductor laser diode 1 emits laser light 10 along a horizontal direction 91. Furthermore, the semiconductor laser device 100 comprises a reflector element 2, partially reflective and partially transmissive for the laser light 10. In particular, the reflector element 2 deflects a first portion 11 of the laser light 10 in a vertical direction 92, while a second portion 12 of the laser light 10 continues to propagate in the horizontal direction 91. The second portion 12 of the laser light 10 is smaller than the first portion 11 of the laser light 10. Preferably, the ratio between the first portion 11 and the sum of the first and second portions 11, 12 is greater than or equal to 0.95 or greater than or equal to 0.99 or greater than or equal to 0.995. Accordingly, the ratio between the second portion 12 and the sum of the first and second portions 11, 12 is less than or equal to 0.05 or less than or equal to 0.01 or less than or equal to 0.005, wherein the second portion 12 is greater than 0% of the laser light 10.

A detector element 3 is arranged at least partially in a beam path of the second portion 12 of the laser light 10. While the first portion 11 is coupled out of the semiconductor laser device 100, the second portion 12 is used to measure the laser light intensity and/or intensity changes by the detector element 3, which for example comprises or is a photodiode.

The semiconductor laser diode 1 is based on, for example, one of InₓGa_{y}Al_{1-x-y}As, InₓGa_{y}Al_{1-x-y}P, or InₓGa_{y}Al_{1-x-y}N, depending on the desired wavelength of the laser light 10 as described in the general part above, with 0≤x≤1, 0≤y≤1, and x+y≤1 in each case. The semiconductor laser diode 1 can be designed as a continuously emitting laser diode or as a pulsed laser diode with a single active region or with a plurality of active regions, in particular in the form of a broad-strip laser.

The semiconductor laser diode 1, the reflector element 2, and the detector element 3 are jointly integrated in the semiconductor laser device 100. In particular, the semiconductor laser diode 1, the reflector element 2, and the detector element 3 may be arranged in a common housing 99 as shown. The housing 99, which may be, for example, a plastic housing, a ceramic housing, a metal housing, or a mixture thereof having lead frames and/or conductor paths, may be surface mountable, in particular, and have a mounting surface oriented perpendicular to the vertical direction 92. Accordingly, during operation, the semiconductor laser diode 1 emits the laser light 10 parallel to the mounting surface. The first portion 11 of the laser light 10 is emitted perpendicular to the mounting surface, so that the semiconductor laser device 100 may be a so-called top-looker package.

Further features and modifications of the semiconductor laser device 100 are explained in connection with the following figures. The description of the following figures mainly refers to differences and further developments compared to preceding exemplary embodiments. Features not described may therefore each be as embodied in preceding exemplary embodiments.

FIG. 2 shows an exemplary embodiment of a semiconductor laser device 100 in which the semiconductor laser diode 1, the reflector element 2 and the detector element 3 are mounted on a mounting surface of a common carrier 6. The carrier 6 may, for example, comprise a semiconductor material, a ceramic material and/or a plastic material and may be in the form of a carrier provided with electrical conductor paths, terminals and/or through-connections, for example as a printed circuit board or as part of a housing. Particularly preferably, electrical contacting of the semiconductor laser diode 1 and the detector element 3 is effected via the mounting surface. As shown, the edge-emitting semiconductor laser diode 1 is mounted on the mounting surface on the carrier 6 in such a way that the laser light 10 generated by the semiconductor laser diode 1 during operation is emitted parallel to the mounting surface along the horizontal direction 91 towards the reflector element 2, while the vertical direction 92 is aligned perpendicular to the mounting surface.

In the exemplary embodiment shown, the semiconductor laser diode 1 is designed as a pulsed broad-strip multimode laser diode whose laser light 10 can exhibit a large divergence, as indicated by the dashed lines. However, due to the close spatial proximity of the semiconductor laser diode 1 to the reflector element 2, no further optical measures are necessary to collimate the laser light 10 prior to beam splitting.

In the exemplary embodiment shown, the reflector element 2 comprises two prisms 21 with a dielectric layer 22 arranged between them, the dielectric layer 22 being arranged at an angle of 45° to the horizontal direction 91. The prisms 21 are, for example, made with or of glass, such as borosilicate glass or quartz glass. The reflector element 2 may thus be formed of two interconnected glass prisms, which are connected to each other via the dielectric layer 22. Alternatively, the prisms 21 may comprise or be made of a plastic. At the interface between the prisms 21 the dielectric layer 22 is applied, the refractive index of which is selected in comparison with the refractive index of the prisms 21 such that the reflection of the first portion 11 and transmission of the second portion 12 described above are achieved. Accordingly, with respect to the first portion 11, the reflector element 2 causes the laser light 10 to be deflected by 90° and thus causes the beam formed by the first portion 11 to be coupled out of the semiconductor laser device 100.

The smaller second portion 12 of the laser light 10, which may for example be 1% of the laser light 10 generated by the semiconductor laser diode as described above, is transmitted through the dielectric layer 22. At least part of it can thus reach the detector element 3, which is mounted behind the reflector element 2 and which is preferably designed as a photodiode.

The semiconductor laser diode 1 and the detector element 3 are optically connected to the reflector element 2 with an optically transparent material 4. For this purpose, as shown in FIG. 2, at least part of the semiconductor laser diode 1, at least part of the reflector element 2 and at least part of the detector element 3 may be covered with the transparent material 4. The transparent material 4 is, for example, an optical silicone or acrylic or other material mentioned in the general part and can be applied by casting, dispensing or dripping, for example. By capillary forces, the still liquid transparent material 4, which is particularly preferably refractive index matched, can enter the gaps between the semiconductor laser diode 1 and the reflector element 2 as well as between the detector element 3 and the reflector element 2 and fill them completely, so that no air gaps remain in the beam path of the laser light in front of or behind the reflector element 2, whereby scattering losses caused by refractive index jumps at interfaces to the air can be avoided.

Furthermore, a non-transparent material 5 is applied over the semiconductor laser diode 1, the detector element 3 and the transparent material 4, and preferably completely covers the aforementioned components as shown. In the shown exemplary embodiment, the non-transparent material 5 is a black epoxy and is applied, for example, by means of casting or a film-assisted molding method. The surface of the reflector element 2 facing away from the carrier 6 forms the light outcoupling surface 23 of the semiconductor laser device 100. The light outcoupling surface 23 is thus formed in particular by a surface of one of the glass prisms 21. The non-transparent material 5 is arranged laterally adjacent to the reflector element 2, the light outcoupling surface 23 being free of the non-transparent material 5 as well as the transparent material 4. As shown, the light outcoupling surface 23 and a surface of the non-transparent material 5 facing away from the carrier 6 form a common surface of the semiconductor laser device 100, which is particularly preferably a planar surface extending perpendicular to the vertical direction 92. Thus, the semiconductor laser device 100 has a continuous planar surface which may be advantageous, for example, with respect to common pick-and-place methods, while the semiconductor laser diode 1, the reflector element 2 and the detector element 3 are protected by the materials 4, 5.

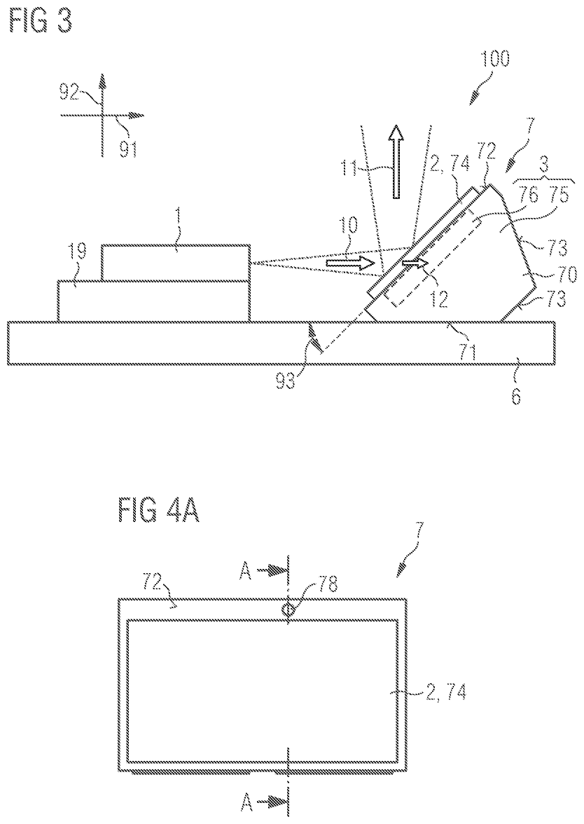

FIG. 3 shows an exemplary embodiment of a semiconductor laser device 100 which, compared to the previous exemplary embodiment, comprises an optoelectronic beam deflection element 7, in which a reflector element 2 and a detector element 3 are integrated. Furthermore, the semiconductor laser diode 1 is purely exemplarily mounted on a submount 19 on the carrier 6, which can for example be made of a metal or a ceramic with good thermal conductivity, such as AlN, and which can provide improved heat dissipation from the semiconductor laser diode 1. Alternatively to the exemplary embodiment shown in FIG. 3, the semiconductor laser device 100 may additionally comprise a transparent material and/or a non-transparent material as described before, which at least partially covers the semiconductor laser diode 1 and/or the beam deflection element 7.

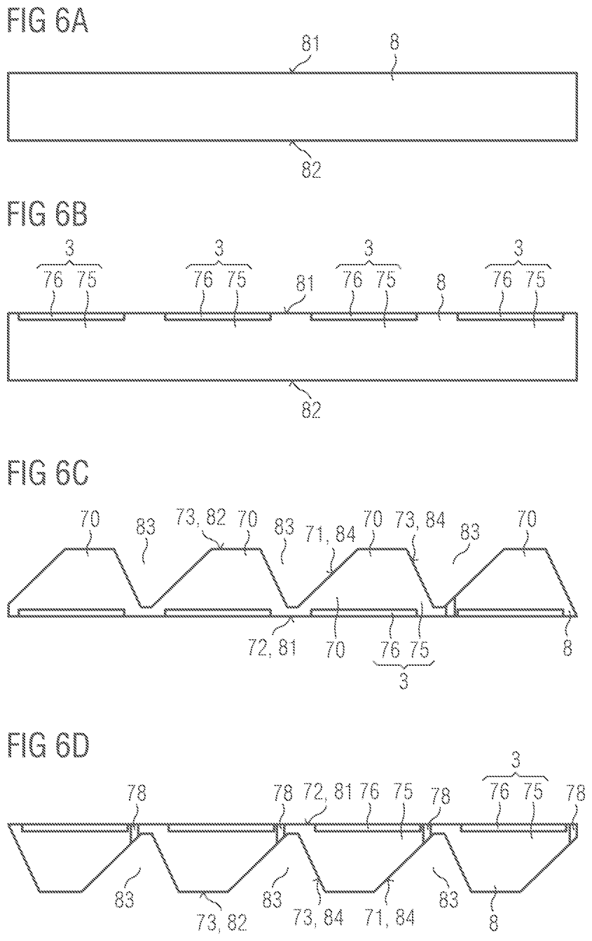

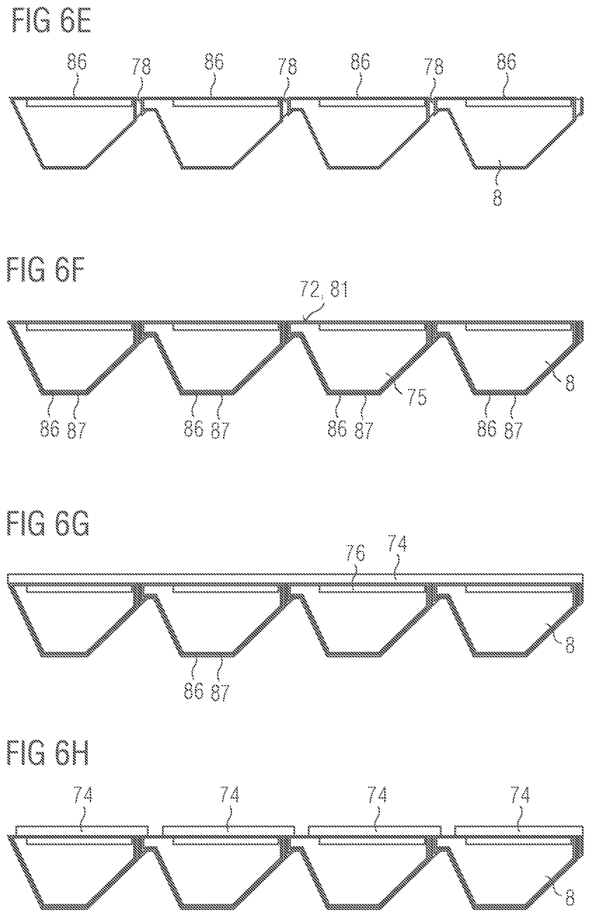

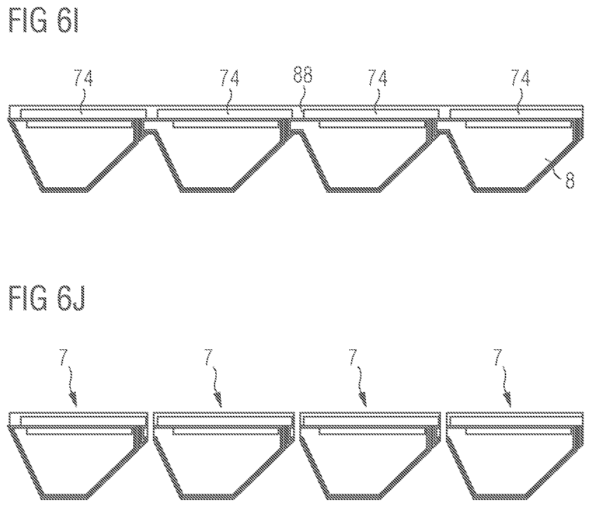

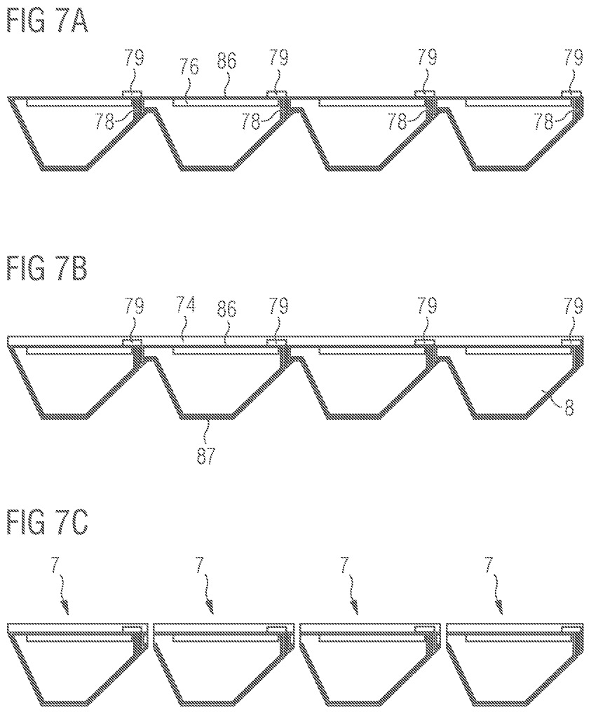

The optoelectronic beam deflection element 7 comprises a semiconductor body 70 having a mounting surface 71, a front surface 72, and rear surfaces 73 different from the mounting surface 71 and the front surface 72. Furthermore, the semiconductor body 70 has side surfaces parallel to the drawing plane. By means of the mounting surface 71, the beam deflection element 7 is mounted on the mounting surface of the carrier 6, for example by soldering or bonding, while the front surface 72, on which a mirror layer 74 forming the reflector element 2 is applied, is arranged facing the semiconductor laser diode 1. The semiconductor body 70 contains silicon and is formed, in particular, from a silicon wafer, as explained in more detail below in connection with FIGS. 6A to 7C. The semiconductor body 70 has such a crystal orientation that the front surface 72 is formed by a crystal surface deviating by 9.74° from the crystallographic 100-surface. The mounting surface 71 is formed by a crystal surface which is a crystallographic 111-surface. The front surface 72 and the mounting surface 71 include an angle 93 of 45°, so that a first portion 11 of the laser light 10 irradiated onto the reflector element 2 during operation along the horizontal direction 91 is deflected in the vertical direction 92 and emitted from the semiconductor laser device 100. The mirror layer 74 is partially transmissive for the laser light 10, so that a second portion 12 of the laser light 10 is transmitted through the mirror layer 74 and can propagate further along the horizontal direction 91. For example, the first portion may be 99% and the second portion may be 1% of the irradiated laser light 10.

The mirror layer 74 forming the reflector element 2 comprises a metal and/or a dielectric layer sequence. The thickness of the metal and/or the dielectric layer sequence are selected such that the described partial reflection and partial transmission of the laser light 10 takes place for splitting the laser light 10 into the first and second portions 11, 12. Depending on the wavelength of the laser light 10, suitable metals include, for example, Al, Au, Ag as well as alloys therewith, wherein Al and/or Ag may be particularly suitable for visible light and Au may be particularly suitable for infrared light. Depending on the wavelength, combinations of metal and semimetal oxides and metal and semimetal nitrides such as SiO₂, Si₃N₄, TiO₂, Al₂O₃ are suitable as materials for the dielectric layer sequence.

The detector element 3 is formed in the semiconductor body 70 on the side of the mirror layer 74 facing the mounting surface 71, so that at least a part of the second portion 12 is irradiated onto the detector element 3. To form the detector element 3, the semiconductor body 70 has differently conductive regions 75, 76, one of which is p-type conductive and one of which is n-type conductive. For example, the region 75 corresponding to the semiconductor body 70 except for the region 76 may be n-conductive, while the region 76 is p-conductive. Reverse doping is also possible. In particular, the p-type region and the n-type region may form a photodiode as the detector element 3. For contacting the detector element 3, the beam deflection element 7 has contact elements (not shown).

As described, the optoelectronic beam deflection element 7 advantageously has a combination of the reflector element 2 and the detector element 3 in the same component, so that only one component to be mounted on the carrier 6 is necessary in addition to the semiconductor laser diode 1 for beam deflection and power measurement. This enables a compact design of the semiconductor laser device 100, since no additional space is required for the detector element 3. The adjustment of the radiation direction from the semiconductor laser device 100 and the detection of the laser light power is possible directly with the laser light beam emitted from the semiconductor laser diode 1, so that influences due to the housing geometry can be reduced compared to usual laser packages. By using the special crystal structure orientation of the semiconductor body 70 as described above, a high-precision 45° flank for forming the mounting surface 71 and thus a high-precision orientation of the reflector element 2 relative to the mounting surface 71 can be achieved, as is also described below. Here, a simple integration of a metallic or dielectric mirror is possible. Further features of the optoelectronic beam deflection element 7 will be explained in connection with the following figures.

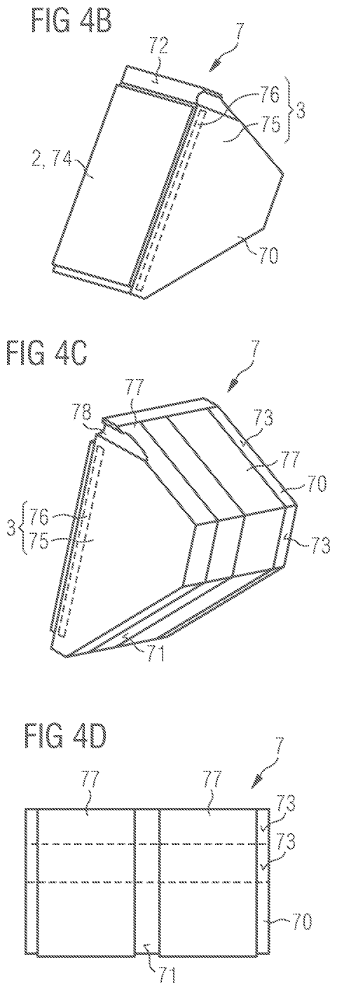

FIGS. 4A to 4D show various views of an optoelectronic beam deflection element 7 for a semiconductor laser device. FIG. 4A shows a view of the front surface 72, while FIGS. 4B and 4C show three-dimensional sectional views of the sectional plane AA indicated in FIG. 4A. FIG. 4D shows a view of the mounting surface 71 and the rear surfaces 73. The following description refers equally to FIGS. 4A to 4D. The beam deflection element 7 is designed as described in connection with FIG. 3 with respect to the semiconductor body 70 and its outer surfaces 71, 72, 73 as well as with respect to the reflector element 2 and the detector element 3. For electrical contacting as well as for mounting the detector element 3, the semiconductor body 70 in the shown exemplary embodiment has, on the mounting surface 71 and the rear surfaces 73, two electrical contact elements 77 in the form of metal layers, at least one of which contacts the region 76 and at least one other of which contacts the region 75. The contact element 77 contacting the region 76 is electrically insulated from the region 75 by an electrically insulating layer not shown. Further, the contact element 77 contacting the region 76 is in electrical contact with an electrical through-connection 78 extending from a rear surface 73 to the front surface 72 so that the doped region 76 adjacent to the front surface 72 can be contacted from the front surface 72. As an alternative to the exemplary embodiment shown, one or both of the contact elements 77 may be arranged, for example, on only one of the rear surfaces 73 or only on the mounting surface 71. At least parts of the contact elements 77 may, for example, form solder pads by means of which the beam deflection element 7 can be fixed to the carrier 6 and be electrically connected. Furthermore, the size, position and shape of the contact elements 77 and the through-connection 78 are to be understood as purely exemplary and can be adapted to the mounting requirements. The contact elements 77 and the through-connection 78 preferably comprise or are made of one or more metals, for example selected from copper, nickel, gold, silver, aluminum, chromium.

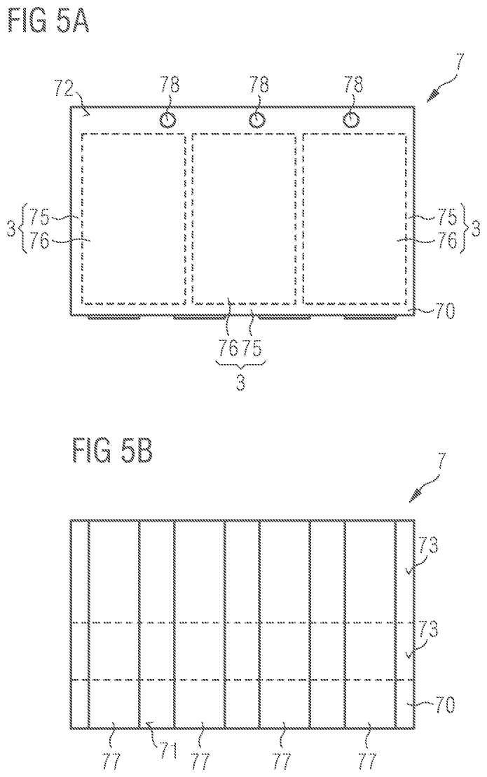

FIGS. 5A and 5B show an exemplary embodiment of an optoelectronic beam deflection element 7 in views corresponding to FIGS. 4A and 4D, which has a plurality of doped regions 76 in the semiconductor body compared to the previous exemplary embodiment. Together with the region 75, each of the regions 76 forms a detector element 3, so that the beam deflection element 7 has a plurality of detector elements 3. In other words, the beam deflection element 7 has a segmented photodiode.

For contacting the detector elements 3, the semiconductor body 70 correspondingly has a plurality of contact elements 77 and through-connections 78, which may be designed as in the previous exemplary embodiment. Here, as shown, the beam deflection element 7 may have a respective contact element 77 with an associated through-connection 78 for each region 76 and a common contact element 77 for contacting the region 75. Due to such a segmented photodiode, the beam deflection element 7 can be used with a plurality of semiconductor laser diodes on a common carrier, wherein separate detection and control of the different semiconductor laser diodes, for example with different wavelengths, is possible with small spacing on the same carrier or in the same housing.

FIGS. 6A to 6J show method steps of a method of manufacturing an optoelectronic beam deflection element 7 for a semiconductor laser device according to an exemplary embodiment. In particular, a plurality of optoelectronic beam deflection elements 7 are manufactured in a wafer process in which process techniques from silicon technology and MEMS technology can be used.

As shown in FIG. 6A, a silicon wafer 8 is provided. The silicon wafer 8 has at least a first main surface 81 and an opposite second main surface 82. The silicon wafer 8 is oriented with respect to its crystal structure such that the main surfaces 81, 82 are formed by crystal surfaces that deviate by 9.74° from the crystallographic 100-surface. For this purpose, the silicon wafer 8 can be oriented accordingly, for example, by suitable sawing of a single crystal. The silicon wafer has a first conductivity type and can be, for example, n-type conductive, for example by appropriate doping. Alternatively, the silicon wafer 8 can also be p-type conductive, in which case the following description applies with correspondingly reversed conductivity types.

At the first main surface 81, p-type regions 76 are produced. The regions 76 are produced, for example, by means of diffusion or implantation of a suitable dopant and, together with the region 75, form the previously described detector elements 3 in the subsequently completed beam deflection elements 7. By means of suitable structured doping, segmented photodiodes can also be produced, as described further above.

From the first main surface 81, the front surface 72 of the semiconductor bodies 70 is formed in the method described herein, as indicated in FIG. 6C, so that the front surfaces of the subsequently completed beam deflection elements 7 are formed by a crystal surface which deviates by 9.74° from the crystallographic 100-surface. By anisotropic etching of the second main surface 82 in conjunction with suitable lithography steps, trenches 83 are formed in the second main surface 82. Depending on the crystal orientation, the silicon wafer 8 is here etched to different extents in different directions, wherein etching in a direction perpendicular to the crystallographic 111-surface is significantly slower than in the other directions. Thus, trenches 83 with side flanks 84 are created in the second main surface 82, at least one of which is formed by the crystallographic 111-surface. Particularly preferably, all side flanks 84 may have this orientation. Due to the orientation of the 100-plane and the 111-plane in the crystal lattice of the silicon wafer 8 with respect to each other and due to the deviation of the main surfaces 81, 82 by 9.74° from the crystallographic 100-surface, at least one side flank 84 of the trenches 83, which form the mounting surfaces 71 in the subsequently completed beam deflection elements 7, includes an angle of 45° with the main surfaces 81, 82. The other side flanks 84 and the remnants of the first main surface 81 form the rear surfaces 73 of the subsequently completed beam deflection elements 7. After forming the trenches 83, the silicon wafer 8 thus forms a composite of previously described semiconductor bodies 70.

In a further method step, as shown in FIG. 6D, openings are created from the first main surface 81 to the opposite side through the silicon wafer 8 by suitable lithography steps and anisotropic etching steps to produce electrical through-connections. For clarity, in FIGS. 6D and 6E, the openings are already identified as electrical through-connections 78, although the method steps described below are still used to complete these. Compared to the exemplary embodiments of FIGS. 4A to 5B, the through-connections 78 in this exemplary embodiment extend from the front surface 72 to the mounting surface 71.

In a further method step, as shown in FIG. 6E, an electrically insulating layer 86 is formed on the surfaces of the silicon wafer 8. This can be done, for example, by oxidizing the surfaces to form an SiO₂ layer. Alternatively, a silicon nitride layer can be created or applied, for example.

As shown in FIG. 6F, an electrically conductive layer 87 is applied in a structured manner to the side opposite the first main surface 81 in conjunction with suitable lithography steps, which layer 87 forms the contact elements and the electrically conductive filling of the through-connections in the finished beam deflection elements 7. At suitable points, the electrically insulating layer 86 is also provided with openings (not shown) to enable contacting of the semiconductor material of the semiconductor body in the region 75.

On the first main surface 81, as shown in FIGS. 6G and 6H, a mirror layer 74 is applied over a large area and then structured by appropriate lithography steps. The mirror layer 74 can be made with or of Ag, Al and/or Au as described further above. Particularly preferably, TiAl, TiAg or Au can be applied as the mirror layer 74. The mirror layer 74 can also serve as an electrical contact of the regions 76, in which case the electrically insulating layer 86 on the first main surface 81 can be provided with suitable openings (not shown). Thereafter, as shown in FIG. 61, an encapsulation layer 88 may be applied to protect the mirror layer 74, comprising or being made of, for example, SiO₂ and/or Si₃N₄. By cutting, for example by sawing or laser cutting, the composite thus produced can be separated into individual optoelectronic beam deflection elements 7, as shown in FIG. 6J.

FIGS. 7A to 7C show method steps of a method according to a further exemplary embodiment in which, in comparison to the previous exemplary embodiment, a dielectric layer sequence is applied as the mirror layer 74 instead of a metallic mirror layer. The method step shown in FIG. 7A succeeds the method step shown in FIG. 6F. For contacting the doped region 76, the electrically insulating layer 86 is opened at least in one area and a contact element 79, for example made of the same material as the contact elements 77, is applied in contact with the through-connection 78. Then, as shown in FIG. 7B, the dielectric layer sequence is applied over it as the mirror layer 74, for example with a TiO₂ layer, an SiO₂ layer and an Si₃N₄ layer. Subsequently, as shown in FIG. 7C and as already explained in connection with FIG. 6J, the wafer is separated by sawing or laser cutting into individual optoelectronic beam deflection elements 7.

The features and exemplary embodiments described in connection with the figures can be combined with each other according to further exemplary embodiments, even if not all combinations are explicitly described. Furthermore, the exemplary embodiments described in connection with the figures may alternatively or additionally have further features according to the description in the general part.

The invention is not limited to the exemplary embodiments by the description based on the same. Rather, the invention encompasses any new feature as well as any combination of features, which in particular includes any combination of features in the patent claims, even if this feature or combination itself is not explicitly stated in the patent claims or exemplary embodiments.

1-6. (canceled)

7. An optoelectronic beam deflection element for a semiconductor laser device, comprising
a semiconductor body (70) having a mounting surface,
a front surface formed at an angle of 45° to the mounting surface, on which a reflector element formed by a mirror layer is applied, and
a detector element formed in the semiconductor body on the side of the mirror layer facing the mounting surface, wherein
the detector element is at least partially formed by a p-type region and an n-type region of the semiconductor body,
the semiconductor body has, on the mounting surface and/or on at least one rear surface different from the mounting surface and the front surface, at least two electrical contact elements, at least one of which contacts the p-type region and at least one other of which contacts the n-type region, and
at least one of the electrical contact elements is in electrical contact with an electrical through-connection extending from a rear surface or the mounting surface to the front surface.

8. The optoelectronic beam deflection element according to claim 7, wherein the semiconductor body comprises silicon.

9. The optoelectronic beam deflection element according to claim 8, wherein the front surface is formed by a crystal surface that deviates by 9.74° from the crystallographic 100-surface.

10. The optoelectronic beam deflection element according to claim 7, wherein the mirror layer comprises a metal and/or a dielectric layer sequence.

11. The optoelectronic beam deflection element according to claim 7, wherein a plurality of detector elements is formed in the semiconductor body.

12. A semiconductor laser device comprising:
an edge-emitting semiconductor laser diode which emits laser light along a horizontal direction during operation;
a reflector element which deflects a first portion of the laser light in a vertical direction while a second portion of the laser light continues to propagate in the horizontal direction; and
a detector element which is arranged at least partially in a beam path of the second portion of the laser light, wherein
at least part of the semiconductor laser diode and at least part of the detector element are covered with a non-transparent material.

13. The semiconductor laser device according to claim 12, wherein at least part of the semiconductor laser diode, at least part of the reflector element, and at least part of the detector element are covered with a transparent material.

14. The semiconductor laser device according to claim 12, wherein the non-transparent material completely covers the transparent material.

15. The semiconductor laser device according to claim 12, wherein the reflector element comprises two prisms with a dielectric layer arranged between them, and the dielectric layer is arranged at an angle of 45° to the horizontal direction.

16. The semiconductor laser device according to claim 15, wherein the semiconductor laser diode, the reflector element and the detector element are arranged on a common carrier, and a surface of the reflector element facing away from the carrier forms a light outcoupling surface of the semiconductor laser device.

17. The semiconductor laser device according to claim 1, wherein the reflector element and the detector element are integrated in an optoelectronic beam deflection element, said optoelectronic beam deflection element comprising:
a semiconductor body having a mounting surface;
a front surface formed at an angle of 45° to the mounting surface, on which a reflector element formed by a mirror layer is applied; and
a detector element formed in the semiconductor body on the side of the mirror layer facing the mounting surface, wherein
the detector element is at least partially formed by a p-type region and an n-type region of the semiconductor body,
the semiconductor body has, on the mounting surface and/or on at least one rear surface different from the mounting surface and the front surface, at least two electrical contact elements, at least one of which contacts the p-type region and at least one other of which contacts the n-type region, and
at least one of the electrical contact elements is in electrical contact with an electrical through-connection extending from a rear surface or the mounting surface to the front surface.
